(19) United States
(12) Patent Application Publication
(10) Pub. No.: US 2025/0056903 A1
(43) Pub. Date: Feb. 13, 2025

(54) PHOTOVOLTAIC MODULE

(71) Applicant: INTERNATIONAL SOLAR ENERGY RESEARCH CENTER KONSTANZ E. V., Konstanz (DE)

(72) Inventors: Andreas HALM, Konstanz (DE); Rüdiger FARNEDA, Radolfzell (DE); Daniel TUNE, Konstanz (DE)

(21) Appl. No.: 18/289,979

(22) PCT Filed: May 19, 2022
(86) PCT No.: PCT/EP2022/063603

§ 371 Date: Nov. 8, 2023

(30) Foreign Application Priority Data
May 20, 2021 (EP) 21174899.1

(51) Int. Cl. H01L 31/05; H01L 31/0224; H01L 31/043

(52) U.S. Cl. CPC H01L 31/0508; H01L 31/022458; H01L 31/043; H01L 31/0516

(57) ABSTRACT

Disclosed is a photovoltaic module (1,2) comprising several serially connected IBC solar cells (100,200,300), wherein each IBC solar cell (100,200,300) has an electrode structure (110,210,310) comprising both a P-type contact electrode structure including at least one P-busbar (112,114,212, 214,312,314) and an N-type electrode structure including at least one N-busbar (116,118,216,218,316,318), wherein at least two of the IBC solar cells (100,200,300) are arranged relative to each other in a partly overlapping manner so that a first region of a back side of a first IBC solar cell (100) is arranged on top of a first region of a front side of a second IBC solar cell (200) and thus creates an overlap region (10,20), wherein at least sections of both the at least one P-busbar (112,114,212,214,312,314) and the at least one N-busbar (116,118,216,218,316,318) of the electrode structure of said first IBC solar cell (100) are located outside of the overlap region (10,30).

Photovoltaic modules that are formed from solar cells are a key component for the generation of renewable energy. Optimization of these modules to increase their efficiency, more specifically the electricity generated on a given area is an ongoing process which covers a variety of different aspects. On the one hand, a lot of research effort is directed at improvement of the conversion efficiency of the individual solar cells. At the same time, however, optimizing the efficient use of the available space, i.e. offering as much active area on a given solar cell and the photovoltaic module formed from such solar cell can also contribute significantly to an improvement of the efficiency that is achieved.

One known way to increase the active area of a given solar cell is the use of IBC (interdigitated back contact) solar cells. In this well-known type of solar cell, electrical contacts are present only on the back side of the solar cell, i.e. the side that faces away from the sun under standard operating conditions. Accordingly, the entire front side that faces the sun can contribute to the generation of electricity and shadowing by the electrical contacts is completely avoided. Detailed information on the structure and production of this class of solar cells can be found for example in
G. Galbiati et al., “Large area back-contact back-junction solar cells with efficiency exceeding 21%,” 2012 IEEE 38th Photovoltaic Specialists Conference (PVSC) PART 2, Austin, TX, USA, 2012, pp. 1-4, doi: 10.1109/PVSC-Vol2.2012.6656700

or
R. Kopecek et al., “ZEBRA technology: low cost bifacial IBC solar cells in mass production with efficiency exceeding 23.5%,” 2020 47th IEEE Photovoltaic Specialists Conference (PVSC), Calgary, AB, Canada, 2020, pp. 1008-1012, doi: 10.1109/PVSC45281.2020.9300503.),
   the content of which is incorporated herein by reference.

Whereas in a naïve approach one might assume at first sight that it may be possible to use the complete area of a given photovoltaic module formed from IBC solar cells directly, simply using a side-by side arrangement, this hope is destroyed quickly by reality. One important reason for this is that the considerable variation of the temperature of the solar cells, e.g. during day-night-cycles, is leading to damage and tension due to thermal and mechanical influence if the respective solar cells are arranged if their edges are in direct contact with each other. Another reason is that there is a production related variation in wafer width, so very small gaps are not achievable due to width variations.

Therefore, traditionally when combining solar cells, especially IBC solar cells, to a photovoltaic module, a cell to cell gap was used in order to avoid damage to the individual cells, thus generating electrically inactive area of the module.

One possibility to avoid a cell to cell gap in a photovoltaic module formed using IBC solar cells that is known from the state of the art, e.g. US 2018/0108796 A1, which may disclose the features of the preamble of claim 1 of this application, is arranging the respective IBC solar cells in a cascaded or shingled manner. In other words, the IBC solar cells are arranged relative to each other in a partly overlapping manner so that a first region of a back side of a first IBC solar cell is arranged on top of a first region of a front side of a second IBC solar cell and thus creates an overlap region. The electrical contact between the respective IBC solar cells is then created by placing the entire busbars of the respective first and second IBC solar cell in the overlap region and providing a busbar contact of the second IBC solar cell on the top of the second IBC solar cell to which the busbar of is connected electrically and mechanically, e.g. by means of an electrically conductive glue.

There are, however, two significant disadvantages of this approach: On the one hand, the need to create a contact between busbars of the respective IBC solar cells increases the minimum size of the overlap regions considerably. In other words, whereas essentially the complete area of the photovoltaic module can be used as active area, there is and has to be a considerable amount of potentially active area of the constituent IBC solar cells forming the photovoltaic module that cannot be used, because it is arranged below another IBC solar cells. Moreover, creation of the “through-contact” in the overlap region on the front side of the IBC solar cell requires additional processing steps in the manufacturing process.

On the other hand, thermal and mechanical effects affect in this arrangement directly the electrical contact between the individual IBC solar cells, which has adverse effect and ultimately increases the risk of failure of the photovoltaic module.

Accordingly, the problem addressed by the present invention is providing a photovoltaic module formed from IBC solar cells in which the constituent IBC solar cells are arranged at least partly in a cascaded or shingled way that uses the active area of the constituent IBC solar cells more efficiently and reduces adverse effects on the electric contact between the constituent IBC solar cells.

This problem is solved by a photovoltaic module with the features of claim 1. The subject matter of the corresponding dependent claims relates to specific embodiments of the invention that may be advantageous.

The photovoltaic module according to the invention comprises several serially connected IBC solar cells, wherein each IBC solar cell has an electrode structure comprising both a P-type contact electrode structure including at least one P-busbar and an N-type electrode structure including at least one N-busbar on the back side of the respective IBC solar cell, wherein at least two of the IBC solar cells are arranged relative to each other in a partly overlapping manner so that a first region of a back side of a first IBC solar cell is arranged on top of a first region of a front side of a second IBC solar cell and thus creates an overlap region.

It should be noted that whereas continuous busbars are used more frequently and are preferred in some embodiments, the term busbar as used in this description includes also pseudo busbars, i.e. busbars that are not continuous but may be interrupted between finger contacts.

According to the invention, at least sections of both the at least one P-busbar and the at least one N-busbar of the electrode structure of said first IBC solar cell are located outside of the overlap region.

Providing sections of the busbars that are located outside of the overlap region not only allows for a reduction of the size of the overlap region, thus making use of a larger part of the active surface of each constituent IBC solar cell, but also allows for creating the electrical contact between the first IBC solar cell and the second IBC solar cell via an electric connection between their respective busbars in a readily accessible region at the back side of the solar cells, which is more simple to create from a processing point of view compared to an electrical contact in the overlap region.

Preferably, said P-type contact electrode structure and said N-type contact electrode structure each comprise substructures that are parallel to each other. This is especially the case if the respective P-type contact electrode structure and the respective N-type contact electrode structure are comb-shaped, wherein the parallel substructures form the teeth of the comb and the busbar or pseudo-busbar forms the back of the comb.

In some variants of this embodiment, said substructures of the P-type contact electrode structure that are parallel to each other and said substructures of the N-type contact electrode substructure that are parallel to each other are configured in an at least partly interdigitated pattern on the back side of the respective IBC solar cell, i.e. at least some of the teeth forming the P-type contact electrode structure are arranged adjacent and parallel to at least some of the teeth forming the N-type contact electrode structure and vice versa in the case of a partly interdigitated pattern, and all of the teeth forming the P-type contact electrode structure are arranged adjacent and parallel to teeth forming the N-type contact electrode structure and vice versa in the case of a completely interdigitated pattern.

Preferably, the entire electrode structure of the first IBC solar cell is located completely outside of the overlap region. In this way, not only the remaining overlap region is reduced further, but adverse mechanical effects and mechanical stress on the electrode structure of the IBC solar cell are also avoided.

Preferably, the electrical contacts that form the serial connection between the first IBC solar cell and the second IBC solar cell are located completely on or adjacent to the back side of the first IBC solar cell and the second IBC solar cell. This allows for an easy creation of these electrical contacts during production of the solar cell module.

In some embodiments, the electrical contacts that form the serial connection between the first IBC solar cell and the second IBC solar cell also provide the mechanical connection between the first IBC solar cell and the second IBC solar cell, thus simplifying the production process.

One possibility to create the electrical contacts that form the serial connection between the first IBC solar cell and the second IBC solar is forming them by metal bands, e.g. flat copper wire referred to as “ribbon” with an optional thin (e.g. 5 to 35 micrometer thick) coating (e.g. SnPb solder). Preferred ribbon dimensions are a width between 2 mm and 0.4 mm, and a thickness between 0.3 mm and 0.1 mm. Another possibility is the use of round wires, preferably with diameters between 2 mm and 0.1 mm as core material, also with an optional thin coating as described above.

Metal bands are well suited for this purpose not only because of their conductivity, but also because their typical mechanical properties are well suited to withstand the mechanical stress that is imposed on them when the photovoltaic module undergoes thermal cycles, e.g. induced by the temperature difference between noon and night on a clear, sunny day, therefore this choice of material for the formation of the electrical contact is also well suited to provide the mechanical connection between the individual IBC solar cells that form the photovoltaic module.

An alternative possibility for creating the electrical contacts that form the serial connection between the first IBC solar cell and the second IBC solar is the application of a foil that is locally conductive on the back side of the IBC solar cells forming the photovoltaic module, e.g. by gluing it to said back side, so that the locally conductive foil forms the back side of the photovoltaic module. For example, such a foil can be a bare Cu foil or a layered system comprising e.g. a front isolation layer (oriented towards the cell side) or rear polymer layers to seal the PV module.

The electrical contact can e.g. be formed by local connections between cell and foil realized e.g. by conductive adhesive gluing, solder paste or laser welding.

According to some embodiments, at least one of the at least one P-busbar and the at least one N-busbar runs orthogonal to an edge of the second IBC solar cell that defines the border of the overlap region. In this way, additional freedom with respect to the choice of the overlap region is obtained.

According to a preferred embodiment, at least both the P-bus-bars and the N-busbars of the electrode structures of both the respective first IBC solar cell and the respective second IBC solar cell are arranged in such a way on the back side of these IBC solar cells that inverting a respective first or second IBC solar cell by performing a rotation by 180° around an axis that is located in the center of the plane defined by the respective wafer on which the respective IBC solar cell is formed, said axis furthermore being orthogonal to said plane, moves the P-busbars into places in space that were previously occupied by N-busbars and vice versa. In this geometry, the connection between several IBC solar cells forming the photovoltaic module can be made very simple, especially by arranging the first IBC solar cell in an inverted orientation relative to the second IBC solar cell, i.e. rotated by 180° relative to the above-mentioned axis.

Whereas naturally the direction in which the fronts respective IBC solar cells are facing remains identical, the above-defined geometry of the busbars leads to a situation in which the P-busbars of the first IBC solar cell are arranged in line with the N-busbars of the second IBC solar cell, in line with the P-busbars of the third IBC solar cell etc., which allows for easy connection of busbars that need to be connected in order to achieve a serial connection between the IBC solar cells of the photovoltaic module.

As shown below in detail for a specific example of a photovoltaic module, the layout of the electrical contacts of the photovoltaic module can be made especially simple if the electrode structure of each of the first IBC solar cell and the second IBC solar cell, respectively, comprises at least two pairs of busbars, each pair of busbars being formed by a P-busbar and an N-busbar running essentially parallel to each other and at a smaller distance from each other than from any other P-busbar or N-busbar belonging to said electrode structure.

A very simple layout is achieved if the electrode structure of each of the first IBC solar cell and the second IBC solar cell, respectively, comprises exactly two pairs of busbars.

According to another embodiment of the invention, the photovoltaic module can comprise at least one IBC solar cell that has been cut in order to reduce the maximum current and thus reduce losses, so that it comprises a cut edge. In this embodiment, the IBC solar cells are arranged in such an orientation that at least one of the cut edges forms a border of the first region of the second IBC solar cell, so that it is shadowed by the first IBC solar cell. In this arrangement, the covered areas are areas that have a reduced output anyway due to losses induced by the cutting in the vicinity of the cut edge.

Photovoltaic modules according to this invention can be formed by a single string of photovoltaic cells. Preferably, however, they are grouped to form arrangements of several strings of photovoltaic cells in an advantageous way. Such a preferred arrangement may comprise at least a first string of photovoltaic cells arranged according to the invention and a second string of photovoltaic cells arranged according to the invention. At least the first string of photovoltaic cells and the second string of photovoltaic cells are arranged relative to each other in a partly overlapping manner so that a first region of a back side of the first string of photovoltaic cells is arranged on top of a first region of a front side of the second string of photovoltaic cells and thus creates an overlap region. In this way, the previous necessity of providing a gap between adjacent strings of photovoltaic cells, which existed for the same reasons as discussed above in the context of gaps between individual solar cells of a string of photovoltaic cells, is also eliminated.

It should be noted that such an arrangement is realized preferably with specific P-type and N-type electrode structures, in which the P-busbars and the N-busbars run orthogonal to an edge of the second IBC solar cell that defines the border of the overlap region, because the shingled structure of the respective string of photovoltaic cells necessitates a slight shift of the photovoltaic modules relative to each other.

Next, the invention is explained in more in detail based on figures that show embodiments thereof. More specifically, the figures show:

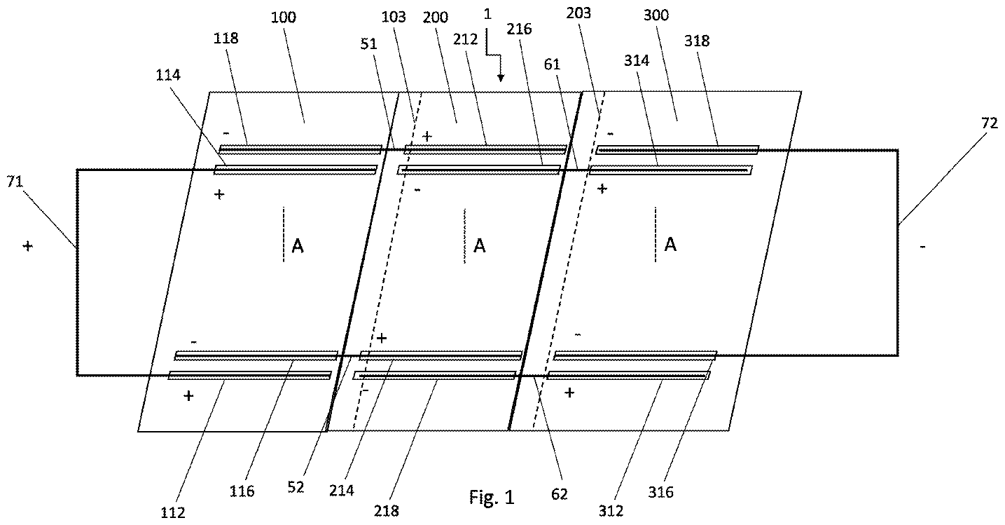

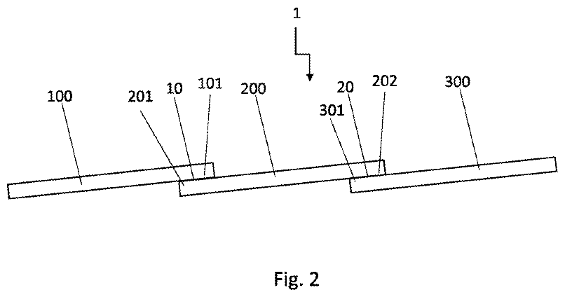

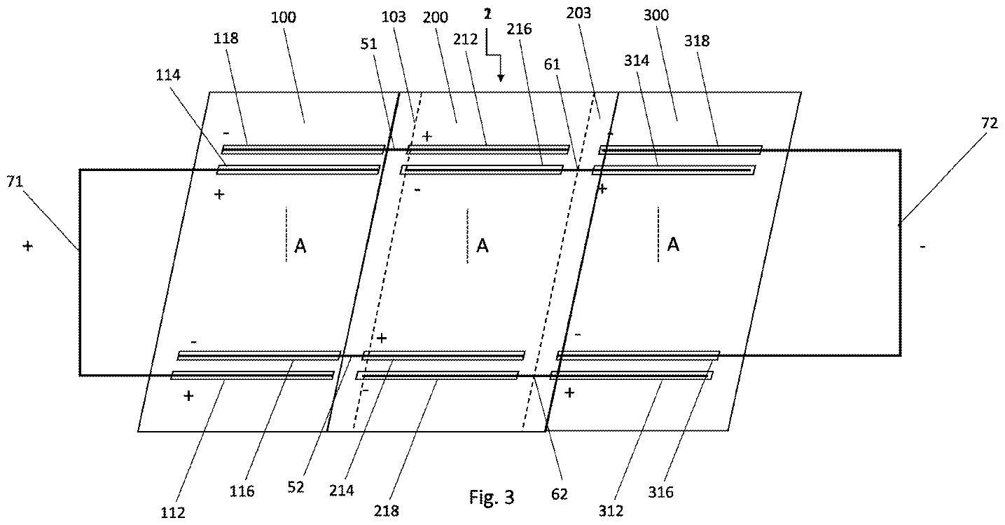

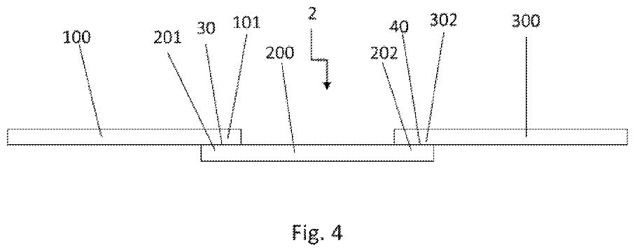

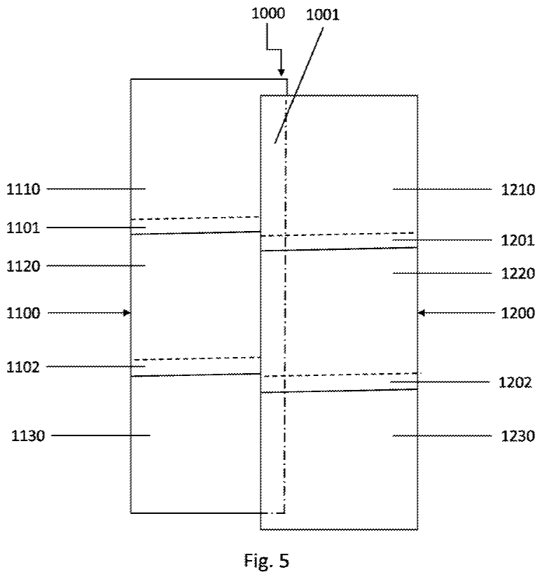

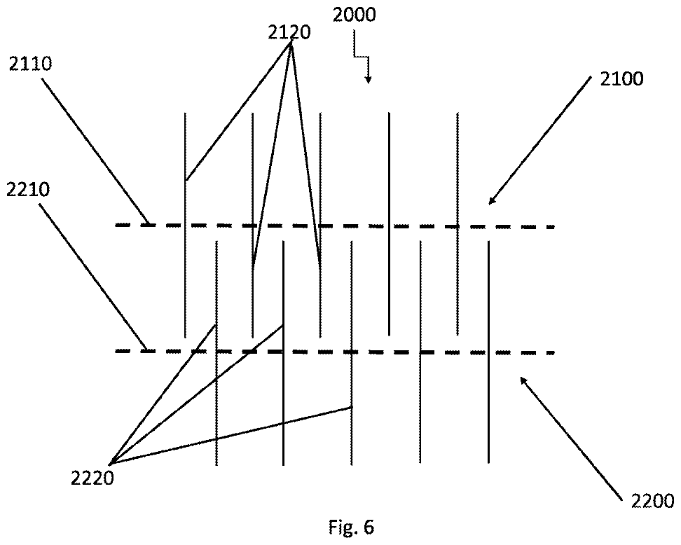

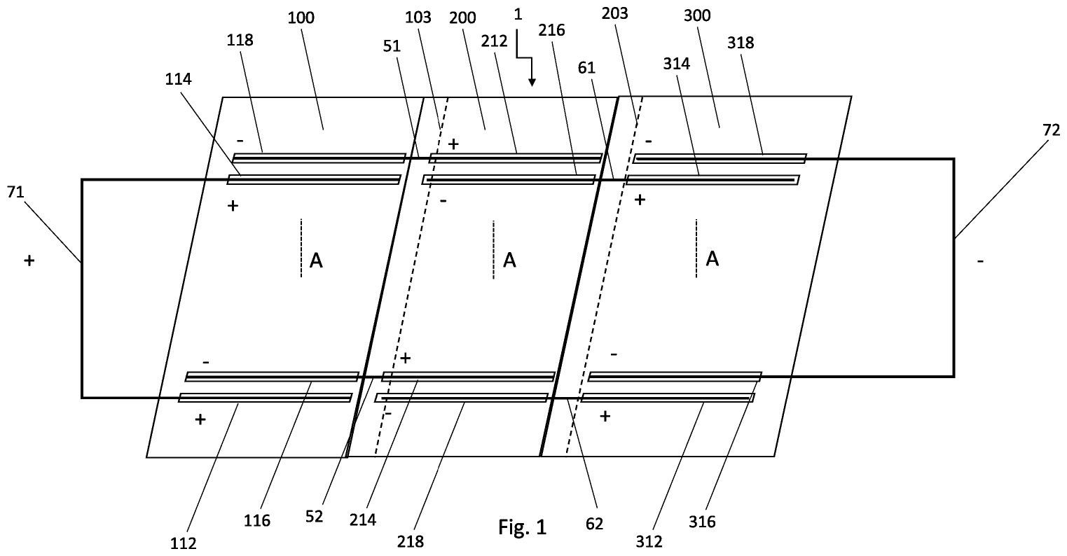

FIG. 1: a first embodiment of a photovoltaic module, shown for the back side,

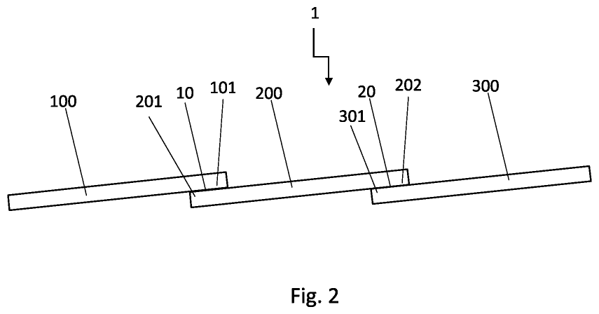

FIG. 2: a side view of the photovoltaic module of FIG. 1,

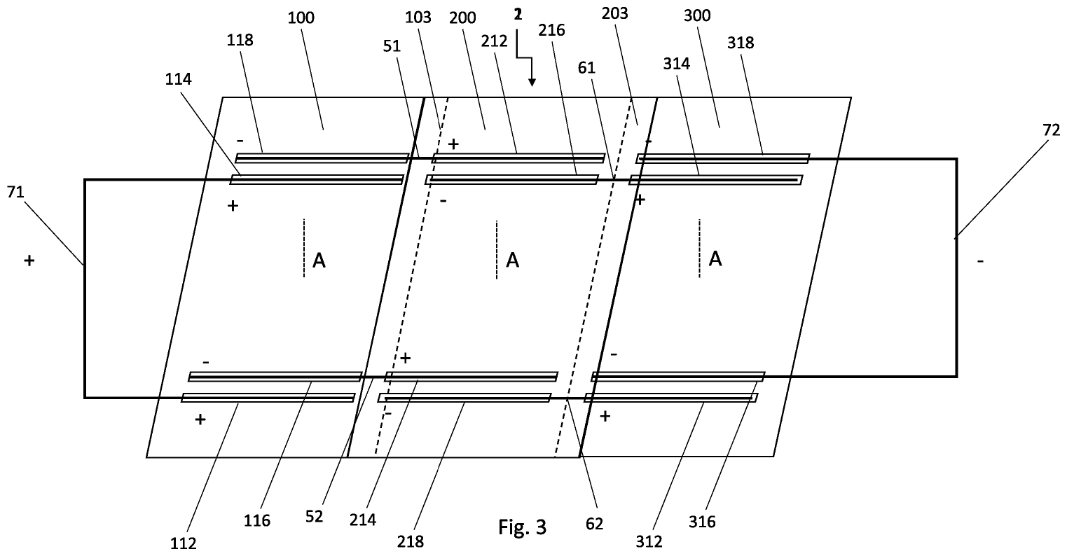

FIG. 3: a second embodiment of a photovoltaic module, shown from the back side,

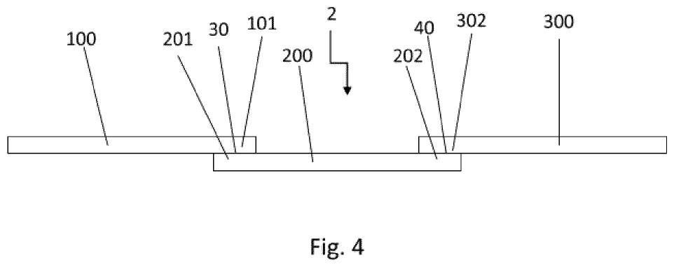

FIG. 4: a side view of the photovoltaic module of FIG. 3,

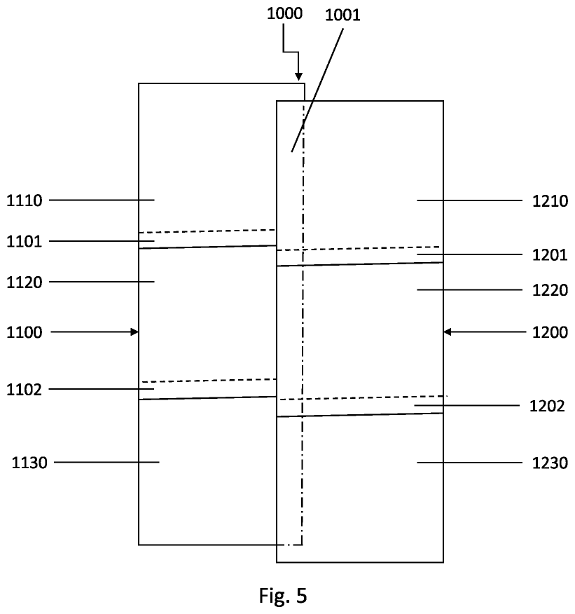

FIG. 5: a photovoltaic module arrangement comprising at least a first string of photovoltaic cells arranged to form a photovoltaic module according to an embodiment of the invention and a second string of photovoltaic cells arranged to form a photovoltaic module according to an embodiment of the invention, and

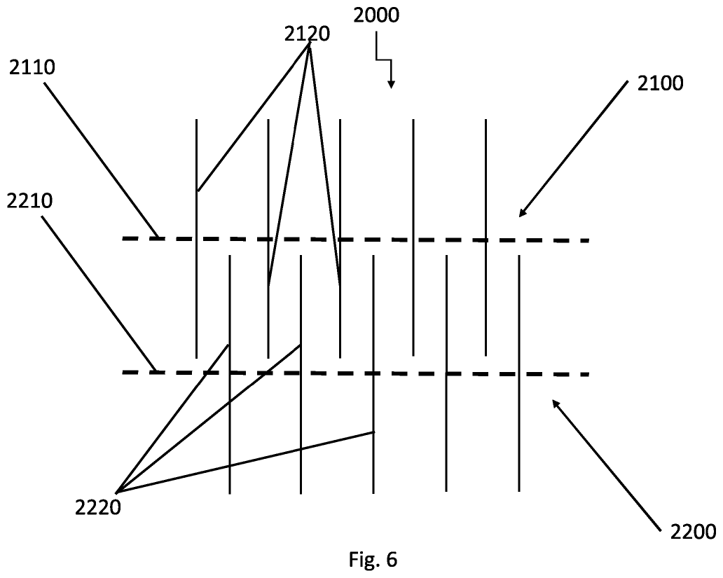

FIG. 6: a schematic simplified representation of an electrode structure of a photovoltaic cell.

FIGS. 1 and 2 show a back view and a side view, respectively, of a photovoltaic module 1 which is formed by a first IBC solar cell 100, a second IBC solar cell 200 and a third IBC solar cell 300. The first IBC solar cell 100, the second solar cell 200 and the third solar cell 300 form a string of solar cells, which is the most simple structure of a photovoltaic module. This number of constituent solar cells is chosen for illustrative purpose only, the principles explained below can be extended easily by the person skilled in the art based on the provided information to photovoltaic modules comprising more constituent solar cells and/or more strings of solar cells.

Each of the IBC solar cells 100,200,300 comprises an electrode structure that is arranged on the back side of the IBC solar cells 100,200,300, i.e. on the side that during operation of the photovoltaic module 1 is facing away from the sun. The electrode structures each comprise both P-type electrode structures and N-type electrode structures. In this example, the P-type electrode structure comprises two P-busbars 112, 114,212,214,312,314, from which conducting fingers that are not shown in the figure for the sake of clarity extend along the back side of the IBC solar cell in orthogonal direction to the P-busbars 112,114,212,214,312,314.

In other words, these fingers form substructures of the P-type electrode structure that are parallel to each other. Together with the respective P-busbar 112,114,212,214,312,314 to which they are connected, they can form e.g. a comb-shaped structure, wherein the form fingers form the teeth of the comb and the respective P-busbar 112,114,212,214,312,314 or, in other embodiments, P-pseudo-busbar forms the back of the comb.

Likewise, in this example the N-type electrode structure comprises two N-busbars 116,118,216,218,316,318, from which conducting fingers that are also not shown in the figures for the sake of clarity extend along the back side of the IBC solar cell 100,200,300 in in orthogonal direction to the N-busbars 116,118,216,218,316,318. Just as in the case of the P-type electrode structure, these fingers form substructures of the N-type electrode structure that are parallel to each other. Together with the respective N-busbar 116,118,216,218,316,318 to which they are connected, they can form e.g. a comb-shaped structure, wherein the form fingers form the teeth of the comb and the respective N-busbar 116,118,216,218,316,318 or, in other embodiments, N-pseudo-busbar forms the back of the comb.

At least some parts of the respective conducting fingers of a P-type electrode structure run parallel and adjacent to at least some parts of the respective conducting fingers of an N-type electrode structure and can form the interdigitated pattern that is encountered in most IBC solar cells.

In order to clarify this terminology, in FIG. 6 a schematic and simplified representation of a complete electrode structure 2000 of a photovoltaic IBC solar cell is shown. The electrode structure 2000 comprises a P-type contact electrode structure 2100 and an N-type contact electrode structure 2200. The P-type contact electrode structure 2100 comprises a P-busbar 2110 and a plurality of fingers 2120 extending orthogonally form the P-busbar 2110. Likewise, the N-type contact electrode structure 2200 comprises an N-busbar 2120 and a plurality of fingers 2220 extending orthogonally form the N-busbar 2210.

Accordingly, both the P-type contact electrode structure 2100 and the N-type contact electrode structure 2200 each comprise substructures, especially the respective sets of fingers 2120 and 2220, respectively, which are parallel to each other.

More specifically, in this example the respective P-type contact electrode structure 2100 and the respective N-type contact electrode structure 2200 are comb-shaped, wherein the parallel substructures formed by the respective sets of fingers 2120,2220 form the teeth of the comb and the respective busbars 2110,2120 form the back of the comb.

Evidently, in the embodiment shown in FIG. 6 said substructures of the P-type contact electrode structure 2100 that are parallel to each other (i.e. the set of fingers 2120) and said substructures of the N-type contact electrode substructure 2200 that are parallel to each other (i.e. the set of fingers 2220) are configured in a partly interdigitated pattern on the back side of the respective IBC solar cell, i.e. at least some of the teeth of the comb represented by the fingers 2120 of the P-type contact electrode structure 2100 are arranged adjacent and parallel to at least some of the teeth of the comb represented by the fingers 2220 of the N-type contact electrode structure 2200 and vice versa.

As becomes evident especially in the side view shown in FIG. 2, the IBC solar cells 100,200,300 are arranged in a shingled way, i.e. in a partly overlapping manner so that a first region 101 of the back side of the first IBC solar cell 100 is arranged on top of a first region 201 of the front side of the second IBC solar cell 200 and thus creates an overlap region 10. Likewise, a first region 202 of the back side of the second IBC solar cell 200 is arranged on top of a first region 301 of the front side of the third IBC solar cell 300, thus creating an overlap region 20. In order to illustrate this in FIG. 1, the position of the edges 103,203,303 of the IBC solar cells 100,200,303 that are not visible in the perspective of FIG. 1 or FIG. 3, respectively, are shown as dotted lines in these figures. As a consequence, edge to edge contact of the respective IBC solar cells 100,200,300 is avoided even if thermal expansion occurs. It should be noted that the size of the overlap regions is exaggerated in the Figures; in practice a small overlap of few mm is sufficient.

As illustrated in FIG. 1, the electrical and mechanical connection between the IBC solar cells 100,200,300 of the photovoltaic module 1 is obtained by metal bands 51,52,61,62 that are arranged on respective bus bars. These metal bands 51,52,61,62 possess not only good electric conductivity, but also the strength and elasticity required for the mechanical connection of the IBC solar cells 100,200,300 to each other. Specifically, the metal bands 51,52,61,62 can be fixed to the back side of the IBC solar cells 100,200,300 in the region of the respective busbars, but not or only partly in the transition region between the neighboring IBC solar cells 100,200,300, which then allows for some play or slack of the metal band in the transition region to accommodate geometric changes induced by expansion and/or contraction under thermal load. It should be noted that the width of the metal bands 51,52,61,62 is chosen smaller than the width of the busbars in the figures only in order to enable showing both the busbar and the metal band.

Essentially, this is also the reason why no figure is presented that shows the embodiment using a back side foil to create the electric and mechanical connections—in this case, the foil covers all other structures on the back side of the photovoltaic module in the back views, and it is not recognizable in the side view.

Returning to FIGS. 1 and 2, as a serial connection between the IBC solar cells 100,200,300 is desired, the N-busbars 116,118 of the first IBC solar cell 100 are connected to the P-busbars 212,214 of the second IBC solar cell 200 and the N-busbars 216,218 of the second IBC solar cell 200 are connected to the P-busbars 312,314 of the third IBC solar cell 300. The P-busbars 112,114 of the first IBC solar cell 100 are connected to the positive connector 71 of the photovoltaic module 1, whereas the N-busbars of the third IBC solar cell 300 are connected to the negative connector 72 of the photovoltaic module 1.

In this example, the respective electrode structures are arranged in such a way on the back side of the IBC solar cells 100,200,300 that two pairs of busbars 112,116;114,118;212,216; 214,218;312,316,314,318 are formed, each pair of busbars being formed by a P-busbar and an N-busbar running essentially parallel to each other and at a smaller distance from each other than from any other P-busbar or N-busbar belonging to said electrode structure.

Moreover, the position of the busbars in the displayed electrode structure is chosen in such a way that inverting an IBC solar cell 100,200,300 by performing a rotation by 180° around an axis A that is located in the center of the plane defined by the respective waver on which the respective IBC solar cell 100,200,300 is formed, which axis A is furthermore orthogonal to said plane, moves the P-busbars into places in space that were previously occupied by N-busbars and vice versa. As a consequence of this choice, all three IBC solar cells 100,200,300 can be produced with the identical layout of the electrode structure on their back side, as the need to align different types of busbars of neighboring IBC solar cells, e.g. N-busbars of IBC solar cell 100 and P-busbars of IBC solar cell 200 and vice versa in the photovoltaic module 1 can simply be met by arranging every second IBC solar cell of the photovoltaic module 1 in the above-described inverted position.

FIGS. 3 and 4 show a back view and a side view, respectively, of a string of photovoltaic cells that forms a most simple photovoltaic module 2 which is obtained by a different arrangement of the first IBC solar cell 100, the second IBC solar cell 200 and the third IBC solar cell 300, but with quite similar electrical and mechanical connections. As the IBC solar cells 100,200,300 and the basic electrical and mechanical connection scheme are identical to the ones used to form the above-described photovoltaic module 1, the same reference numerals are used and a repetition of the detailed description of the IBC solar cells 100,200,300 is not necessary but can be replaced by reference to the corresponding explanations in the context of FIGS. 1 and 2.

However, as can be seen in the side view of FIG. 4, and recognized when analyzing the broken lines that are used to indicate the overlap between the IBC solar cells 100,200,300 in FIG. 3, in the photovoltaic module 20 the IBC solar cells 100,200,300 are arranged in two planes rather than in a shingled way, as was the case in the photovoltaic module 10 described above. Accordingly, whereas the overlap region 30 is once again formed by a first region 101 of the back side of the first IBC solar cell 100 being arranged on top of a first region 201 of the front side of the second IBC solar cell 200, this time a first region 302 of the back side of the third IBC solar cell 300 is arranged on top of a second region 202 of the front side of the second IBC solar cell 300, thus creating an overlap region 40.

FIG. 5 shows a photovoltaic module arrangement 1000 that is formed as an arrangement comprising a first string of photovoltaic cells 1200 which essentially corresponds to the most simple photovoltaic module according to an embodiment of the invention with solar cells 1210,1220,1230 that are arranged in a shingled way, so that overlap regions 1201,1202 are created and a second string of photovoltaic cells 1100 which essentially corresponds to the most simple photovoltaic module according to an embodiment of the invention with solar cells 1110,1120,1130 that are arranged in a shingled way. The photovoltaic module arrangement 1000 of this example thus corresponds to a photovoltaic module that is put together from two more simple photovoltaic (sub-) modules formed by strings of photovoltaic cells 1100,1200.

The first string of photovoltaic cells 1200 and the second string of photovoltaic cells 1100 are arranged relative to each other in a partly overlapping manner so that a first region of a back side of the first photovoltaic module 1200 is arranged on top of a first region of a front side of the second string of photovoltaic cells 1100 and thus creates an overlap region 1001. In this way, it is possible to eliminate the need to leave gaps between the individual strings of photovoltaic cells as well.

### REFERENCE NUMERALS

1,2 photovoltaic module
10,20,30,40 overlap region
51,52,61,62 metal band
71 positive connector
72 negative connector
100,200,300,1110,1120,1130,
1210,1220,1230 IBC solar cell
101, 102, 201, 202, 301, 302 region
103,203,303 edge
112,114,212,214,312,314 P-busbar
116,118,216,218,316,318 N-busbar
1000 photovoltaic module arrangement
1001,1101,1102,1201,1202 overlap region
1100,1200 string of photovoltaic cells
2000 electrode structure
2100 P-type contact electrode
structure
2110 P-busbar
2120 fingers
2200 N-type contact electrode
structure
2210 N-busbar
2220 fingers
A axis

1. A photovoltaic module (1,2) comprising several serially connected IBC solar cells (100,200,300), wherein each IBC solar cell (100,200,300) has an electrode structure (110,210,310) comprising both a P-type contact electrode structure including at least one P-busbar (112,114,212, 214,312,314) and an N-type contact electrode structure including at least one N-busbar (116,118,216,218,316,318), on the back side of the respective IBC solar cell (100,200,300),
wherein at least two of the IBC solar cells (100,200,300) are arranged relative to each other in a partly overlapping manner so that a first region of a back side of a first IBC solar cell (100) is arranged on top of a first region of a front side of a second IBC solar cell (200) and thus creates an overlap region (10,20)
characterized in that at least sections of both the at least one P-busbar (112,114,212,214,312,314) and the at least one N-busbar (116,118,216,218,316,318) of the electrode structure of said first IBC solar cell (100) are located outside of the overlap region (10,30).

2. The photovoltaic module (1,2) of claim 1,
wherein said P-type contact electrode structure and said N-type contact electrode structure each comprise substructures that are parallel to each other.

3. The photovoltaic module of claim 2, wherein said substructures of the P-type contact electrode structure that are parallel to each other and said substructures of the N-type contact electrode substructure that are parallel to each other are configured in an at least partly interdigitated pattern on the back side of the respective IBC solar cell (100,200,300).

4. The photovoltaic module (1,2) of claim 1,
wherein the entire electrode structure (110) of the first IBC solar cell (100) is located completely outside of the overlap region (10,30).

5. The photovoltaic module (1,2) of claim 1,
wherein the electrical contacts that form the serial connection between the first IBC solar cell (100) and the second IBC solar cell (200) are located completely on or adjacent to the back side of the first IBC solar cell (100) and the second solar cell (200).

6. The photovoltaic module (1,2) of claim 1,
wherein the electrical contacts that form the serial connection between the first IBC solar cell (100) and the second IBC solar cell (200) also provide the mechanical connection between the first IBC solar cell (100) and the second IBC solar cell (200).

7. The photovoltaic module (1,2) of claim 1,
wherein the electrical contacts that form the serial connection between the first IBC solar cell (100) and the second IBC solar cell (200) are formed by metal bands (51,52,61,62).

8. The photovoltaic module (1,2) of claim 1,
wherein the electrical contacts that form the serial connection between the first IBC solar cell (100) and the second IBC solar cell (200) are formed by a locally conductive foil.

9. The photovoltaic module (1,2) of claim 8,
wherein the locally conductive foil forms the back side of the photovoltaic module (1,2).

10. The photovoltaic module (1,2) of claim 1,
wherein at least one of the at least one P-busbar (112, 114,212,214,312,314) and the at least one N-busbar (116, 118,216,218,316,318) runs orthogonal to an edge of the second IBC solar cell (200) that defines the border of the overlap region (10,30).

11. The photovoltaic module (1,2) of claim 1,
wherein at least both the P-busbars (112,114,212,214,312, 314) and the N-busbars (116,118,216,218,316,318) of the electrode structures of both the respective first IBC solar cell (100) and the respective second IBC solar cell (200) are arranged in such a way on the back side of these IBC solar cells (100,200) that inverting a respective first or second IBC solar cell (100,200) by performing a rotation by 180° around an axis that is located in the center of the plane defined by the respective waver on which the respective IBC solar cell (100,200) is formed, said axis furthermore being orthogonal to said plane, moves the P-busbars (112,114,212,214,312,314) into places in space that were previously occupied by N-busbars (116,118,216,218,316,318) before said rotation and vice versa.

12. The photovoltaic module (1,2) of claim 11,
wherein the first IBC solar cell (100) is inverted relative to the second IBC solar cell (200).

13. The photovoltaic module (1,2) of claim 1,
wherein the electrode structure of each of the first IBC solar cell (100) and the second IBC solar cell (200), respectively, comprises at least two pairs of busbars (112,116;114,118;212,216;214,218;312,316;314,318), each pair of busbars being formed by a P-busbar (112,114,212, 214,312,314) and an N-busbar (116,118,216,218,316,318) running essentially parallel to each other and at a smaller distance from each other than from any other P-busbar (112,114,212,214,312,314) or N-busbar (116,118,216, 218,316,318) belonging to said electrode structure.

14. The photovoltaic module (1,2) of claim 13,
wherein the electrode structure of each of the first IBC solar cell (100) and the second IBC solar cell (200), respectively, comprises exactly two pairs of busbars (112, 116;114,118;212,216;214,218;312,316;314,318).

15. The photovoltaic module (1,2) of claim 1,
wherein at least one of the IBC solar cells (100,200,300) has been cut so that it comprises a cut edge, wherein the IBC solar cells (100,200,300) are arranged in such an orientation that at least one of the cut edges forms a border of the first region of the second IBC solar cell, so that it is shadowed by the first IBC solar cell.

16. A photovoltaic module arrangement (1000) comprising at least a first string of photovoltaic cells (1200) arranged as in a photovoltaic module according to claim 1 and a second string of photovoltaic cells (1100) arranged as in a photovoltaic module, wherein at least the first string of photovoltaic cells (1200) and the second string of photovoltaic cells (1100) are arranged relative to each other in a partly overlapping manner so that a first region of a back side of the first string of photovoltaic cells (1200) is arranged on top of a first region of a front side of the second string of photovoltaic cells (1100) and thus creates an overlap region (1001).
